(19) United States
(12) Patent Application Publication
(10) Pub. No.: US 2024/0379833 A1
(43) Pub. Date: Nov. 14, 2024

(54) AMBIPOLAR SEMICONDUCTOR-BASED TRANSISTOR AND METHOD

(71) Applicant: KING ABDULLAH UNIVERSITY OF SCIENCE AND TECHNOLOGY, Thuwal (SA)

(72) Inventors: Xiaohang LI, Thuwal (SA); Saravanan YUVARAJA, Thuwal (SA)

(21) Appl. No.: 18/691,610

(22) PCT Filed: Sep. 14, 2022
(86) PCT No.: PCT/IB2022/058660

§ 371 Date: Mar. 13, 2024

Related U.S. Application Data
(60) Provisional application No. 63/274,142, filed on Nov. 1, 2021.
(60) Provisional application No. 63/243,888, filed on Sep. 14, 2021.

(51) Int. Cl. H01L 29/775; H01L 27/092; H01L 29/06; H01L 29/24; H01L 29/423; H01L 29/66; H01L 29/786

(52) U.S. Cl. CPC H01L 29/775; H01L 27/092; H01L 29/0673; H01L 29/068; H01L 29/24; H01L 29/42392; H01L 29/66439; H01L 29/7869; H01L 29/78696

(57) ABSTRACT

An ambipolar, gate all around, semiconductor-based transistor includes a substrate, a first-type channel structure located on the substrate, the first-type channel structure having a gate region, a source region, and a drain region, a second-type material located on all sides of the gate region of the first-type channel structure, but not on the source region and the drain region, a dielectric material fully surrounding the second-type material on all the external surface of the gate region, a gate electrode located on the dielectric material, a source electrode located on the source region, and a drain electrode located on the drain region. The first-type is one of p- or n-type and the second type is another of the p- or n-type.

### CROSS-REFERENCE TO RELATED APPLICATIONS

This application claims priority to U.S. Provisional Patent Application No. 63/243,888, filed on Sep. 14, 2021, entitled “GROUNDBREAKING AMBIPOLAR GATE-ALL-AROUND OXIDE TRANSISTORS FOR INTEGRATED CIRCUITS,” and U.S. Provisional Patent Application No. 63/274,142, filed on Nov. 1, 2021, entitled “DOME AND FLAT FINS GATE-ALL-AROUND AMBIPOLAR TRANSISTORS,” the disclosures of which are incorporated herein by reference in their entirety.

### BACKGROUND

### Technical Field

Embodiments of the subject matter disclosed herein generally relate to a complementary metal-oxide semiconductor (CMOS)-based transistor, and more particularly, to an ambipolar transistor that uses a semiconductor material like Ga₂O₃ for the gate region.

### Discussion of the Background

Wide-bandgap (WBG) semiconductor-based electronic devices are indispensable for applications that demand large voltage, high current carrying capacity, and negligible power loss. Unlike conventional semiconductors, one of the highlighting features that placed the WBG materials in the limelight is high critical electric field density. In the past two decades, extensive research has been carried out using beta-phase (β-Ga₂O₃) owing to its high field density compared to other WBG semiconductors. Besides field density, Ga₂O₃ based devices possess exceptional stability in harsh conditions, excellent optical transmittance, and outstanding electrical field breakdown, due to the ultra-high bandgap (4.5-4.9 eV) property. Recently, these Ga₂O₃ properties have driven the researchers to develop various transistor topologies such as Metal-oxide semiconductor field-effect transistor (MOSFET), Metal-semiconductor field-effect transistor (MESFET), and Modulation doped field-effect transistor (MODFET) for power electronics application.

In early 2012, top gated MESFET was reported to have Sn-doped Ga₂O₃ material as a channel layer on the surface of native Ga₂O₃ substrate. This 20-μm channel length device exhibited decent breakdown voltage (V_{br}) and effective breakdown field (E_{br}) at 200 V and 0.1 MV/cm, respectively. Recently, the costly Ga₂O₃ substrate was replaced by the cheap and widely used c-plane sapphire substrate to grow high-quality Sn-doped α-Ga₂O₃ as a channel layer to realize a top-gated MESFET device. This device exhibited an excellent current ratio (Iₒₙ/I_{off}) around 1×10⁷, but poor V_{br} ˜40 V. However, some significant setbacks such as high leakage current density, greater threshold voltage, and poor gate control affect the growth of MESFET device topology. As an alternative, a gate dielectric layer was introduced between the gate electrode and channel layer to fabricate the MOSFET structure.

In late 2015, a 25 nm Al₂O₃ gate dielectric layer was deposited on top of the Sn-doped Ga₂O₃ material to realize a top gated MISFET structure. Interestingly, this device exhibited 370 V and 0.46 MV/cm as breakdown voltage and effective breakdown field, respectively, much better than its MESFET counterpart. An innovative Ga₂O₃ area-plated MOSFET was developed by passivating the channel layer with Silicon dioxide (SiO₂). This device has shown exceptional V_{br} around 745 V, but E_{br} was considerably low ˜0.1 MV/cm. It is important to note that the maximum saturation current density is less than 1.1 mA/mm, and the higher leakage current density is around 0.5 μA/mm, using top-gated MOSFET. This poor current density and high gate leakage are mainly due to the weak gate electric field management over charges in the channel region. To overcome this problem, the Fin-field effect transistor (Fin-FET) structure has been extensively explored since 2010. Naturally, this structure produces a reasonable gate control over the channel current from 3 facet sides, unlike conventional lateral topology. Li et al. (W. Li, K. Nomoto, Z. Hu, T. Nakamura, D. Jena and H. G. Xing, “Single and multi-fin normally-off Ga2O3 vertical transistors with a breakdown voltage over 2.6 kV,” 2019 IEEE International Electron Devices Meeting (IEDM), 2019, pp. 12.4.1-12.4.4) reported the outstanding performance of Ga₂O₃ vertical fin transistor with 130 cm²/V·s channel mobility having a lower threshold voltage around −3 V. In the following year, a Fin-FET device was fabricated using Sn-doped Ga₂O₃ grown on a native Mg-doped Ga₂O₃ substrate. Using this structure, the threshold voltage slightly improved to −1.5 V, having a good Iₒₙ/I_{off} ratio of about 105. Recently, Hu et al. (Z. Hu et al., “1.6 kV Vertical Ga2O3 FinFETs With Source-Connected Field Plates and Normally-off Operation,” 2019 31st International Symposium on Power Semiconductor Devices and ICs (ISPSD), 2019, pp. 483-48) reported Ga₂O₃ based vertical Fin-FET breaks down at 1.6 kV with a decent 30 mA/mm current density and poor 0.2 μA/mm leakage current density. From the reported Ga₂O₃ Fin-FET transistors, it is noted that their performance has critical limitations that impede their growth to meet the market requirements. This is mainly attributed to the lack of the device design having excellent gate electric field control to achieve normally-off operation with high saturation current density and negligible leakage current.

Over the past two decades, researchers were focusing to design and develop the performance of discrete Ga₂O₃ power devices for various applications. However, in power electronics, the main function of these WBG transistors is just to control the flow of current and handle high voltage breakdown. The core function of the power electronics platform mainly depends on the smart development of monolithic integrated circuits (IC) like peripheral blocks having logic units. These blocks are commonly used to drive and protect the operation of small WBG transistor units. Despite the increase in investigating the state-of-the-art Ga₂O₃ transistors, there are still hard challenges involved in realizing Ga₂O₃ based monolithic IC chips. The first and foremost problem is the lack of reliable and matured p-type transistor devices. It is important to note that the reported Ga₂O₃ units are high performing n-channel devices, which are not suitable to design and integrate them to develop a WBG IC platform. The second major issue is the absence of a method to monolithically integrate both p-type and n-type Ga₂O₃ based transistors on a single platform to realize the compact and energy efficient logic circuits.

Thus, there is a need for a new transistor that is capable of taking advantage of the Ga₂O₃ or similar technology but also to provide p-type capabilities so that the new transistor is ambipolar and can be integrated with the CMOS technologies.

### BRIEF SUMMARY OF THE INVENTION

According to an embodiment, there is an ambipolar, gate all around, semiconductor-based transistor that includes a substrate, a first-type channel structure located on the substrate, the first-type channel structure having a gate region, a source region, and a drain region, a second-type material located on an entire external surface of the gate region of the first-type channel structure, but not on the source region and the drain region, a dielectric material fully surrounding the second-type material on an entire external surface of the gate region, a gate electrode located on the dielectric material, a source electrode located on the source region, and a drain electrode located on the drain region. The first-type material is one of p- or n-type and the second-type material is another of the p- or n-type.

According to another embodiment, there is an inverter that includes a first ambipolar, gate all around, semiconductor-based transistor having (1) a first-type channel structure made of a semiconductor material and (2) a second-type material, a second ambipolar, gate all around, semiconductor-based transistor having (1) another first-type channel structure made of the semiconductor material and (2) another second-type material, a first electrical connection between drain regions (D) of the first and second ambipolar, gate all around, semiconductor-based transistors, and a second electrical connection between source regions (S) of the first and second ambipolar, gate all around, semiconductor-based transistors. The first-type is one of p- or n-type and the second type is another of the p- or n-type.

According to yet another embodiment, there is a method of making an ambipolar, gate all around, semiconductor-based transistor, and the method includes a step of providing a first substrate, a step of growing a first-type channel structure on the first substrate, the first-type channel structure having a gate region, a source region, and a drain region, a step of etching the gate region to form plural fins, a step of depositing a second-type material on all but one portion of the gate region of the first-type channel structure, but not on the source region and the drain region, a step of forming a dielectric material to surround the second-type material on all but one portion of the gate region, a step of depositing a gate electrode on the dielectric material, a source electrode on the source region, and a drain electrode on the drain region, a step of forming a second substrate on the first-type channel structure, a step of removing the first substrate, and a step of depositing the second-type material on the one portion of the gate region so that an entire external surface of the gate region are covered by the second-type material. The channel structure is made of a Ga₂O₃ material.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of a Ga₂O₃ GAA structure formed on silicon substrate;

FIG. 2A illustrates the transfer behavior of the structure of FIG. 1 and FIG. 2B illustrates the output behavior of the same structure;

FIGS. 3A and 3B illustrate an ambipolar Ga₂O₃/NIO GAA structure formed on a silicon substrate;

FIG. 4A illustrates the transfer behavior of the structure of FIGS. 3A and 3B and FIG. 4B illustrates the output behavior of the same structure;

FIG. 5 illustrates a method for making an ambipolar Ga₂O₃/NiO GAA transistor;

FIG. 6 illustrates a configuration of an ambipolar monochannel Ga₂O₃/NiO gate all around (GAA) structure formed on a non-silicon substrate;

FIG. 7A illustrates a square type cross-section of the structure shown FIG. 6 while FIG. 7B illustrates a circle type cross-section of the structure shown in FIG. 6;

FIG. 8A illustrates the transfer behavior of the structure of FIG. 7 and FIG. 8B illustrates the output behavior of the same structure;

FIG. 9 illustrates a method for making an ambipolar monochannel Ga₂O₃/NIO GAA transistor;

FIG. 10 illustrates an ambipolar multichannel Ga₂O₃/NiO GAA structure formed on a non-silicon substrate;

FIG. 11A illustrates the transfer behavior of the structure of FIG. 10 and FIG. 11B illustrates the output behavior of the same structure;

FIG. 12 illustrates the structure of an ambipolar GAA inverter circuit that uses two Ga₂O₃/NiO transistors;

FIGS. 13A and 13B illustrate the behavior of the output voltage as a function of the input voltage for the ambipolar GAA inverter circuit for opposite bias voltages;

FIG. 14 illustrates a NOR logic circuit built with the transistors noted above;

FIG. 15 illustrates a NAND logic circuit built with the transistors noted above;

FIG. 16 illustrates the transient output response obtained from integrated NOR and NAND logic circuits based on the ambipolar GAA inverter circuit;

FIGS. 17A to 17D illustrate an ambipolar Ga₂O₃/NiO GAA transistor formed with different shaped-fins; and

FIG. 18 is a method for manufacturing the transistor shown in FIGS. 17A to 17D.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to an ambipolar transistor that uses n-channel Ga₂O₃ and p-channel Nickel oxide (NiO) on the Ga₂O₃-on-Si gate all around platform. However, the embodiments to be discussed next are not limited to Ga₂O₃ semiconductor materials, p-channel NiO or Fin-FET structures, but may be applied to other semiconductor materials and structures, like silicon, SiGe, 2D materials, InGaAlN, SiC, III-V materials, oxides, etc., to p-type wide bandgap semiconductor materials or Fin-FET transistor structures. An “ambipolar transistor” is a transistor that uses both positive charge carriers (holes) and negative charge carriers (electrons). This is different from a unipolar transistor that uses only positive or only negative charge carriers.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a novel ambipolar transistor with improved high charge carrier mobility, low threshold voltage and ideal turn-OFF characteristics is introduced. While the transistor discussed herein can use any semiconductor material, for enabling one skilled in the art, a specific Ga₂O₃-based transistor is discussed next. However, this embodiment should not be construed to limit the transistor to the Ga₂O₃ material. In one application, a multichannel GAA Ga₂O₃ transistor with good electrical and thermal stability is introduced. The method used for making these transistors achieves a monolithic integration of two identical ambipolar transistors (MOSFETs, or MOS), i.e., Twin MOS (TMOS) and successfully supports basic logic operations including NOT, NOR and NAND.

In one application, an innovative ambipolar transistor is obtained by combining n-channel Ga₂O₃ (or other WBG or non-WBG semiconductor materials) and p-channel Nickel oxide (NiO) materials on the Ga₂O₃-on-Si GAA platform. To realize excellent gate field control, in one embodiment, a fabrication method for completely wrapping all four sides of the ambipolar channel with the gate field is presented. As a result, the GAA ambipolar Ga₂O₃ based Fin-FET is presented in one embodiment. In yet another embodiment, plural Ga₂O₃ nanochannels were inserted in the transistor to achieve ultra-high saturation current density, extremely low ON-resistance with ideal normally-off ambipolar transistor characteristics. Furthermore, this ambipolar device possess special auto-configurable feature that are able to self-tune from p-type to n-type and vice-versa based on the external bias applied. Using this feature, one embodiment presents integrated GAA ambipolar transistors to demonstrate TMOS logic circuits including NOT, NOR and NAND operations. These circuits shown good signal-to-noise ratio margins and quick ON-OFF transition process with low power consumption and gate leakage properties. These embodiments are now discussed in more detail.

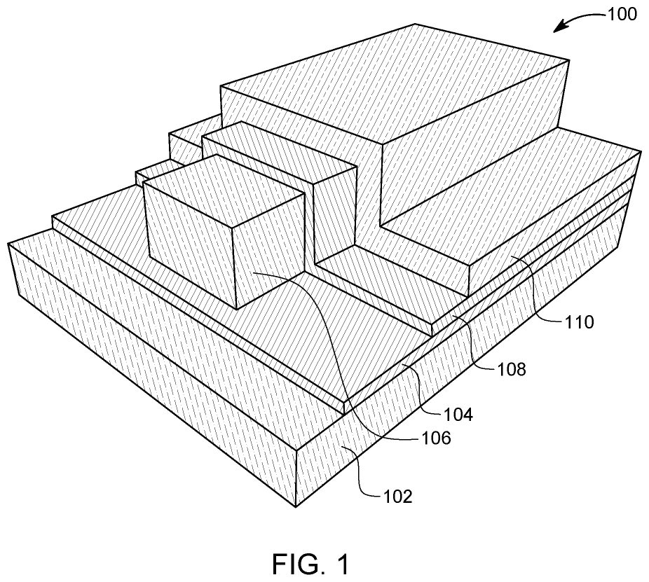

FIG. 1 shows a cross-sectional view of a Ga₂O₃ Fin-FET structure that is part of a transistor 100. Although the structure, comprising the gate region, shown in FIG. 1 does not show the source and drain regions, in this application, this structure is sometimes referred to as a transistor. The same is true for the other drawings in this application. The structure has a Si substrate 102 on which an undoped layer of u-Ga₂O₃ 104 is formed. Note that other materials may be used for the substrate 102 such as sapphire, AlN, GaN, GaAs, metal, Ga₂O₃. An n-doped Ga₂O₃ channel layer 106 (also called herein “channel structure”) is located over the u-Ga₂O₃ layer 104 and it constitutes the channel of the transistor. A dielectric layer 108 of HfO₂ is formed over the channel layer 106 and an electrode 110, e.g., including Au and Ti, is located over the dielectric layer. In this way, a n-type n-Ga₂O₃ transistor is formed.

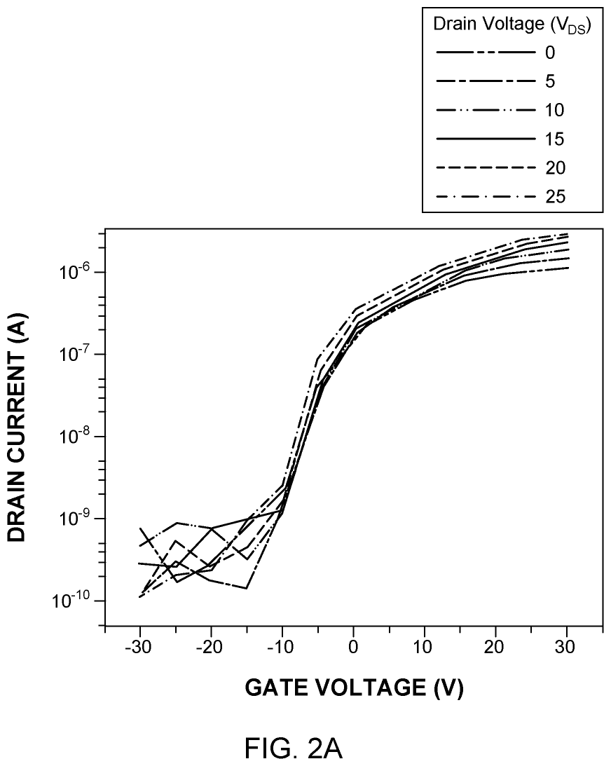

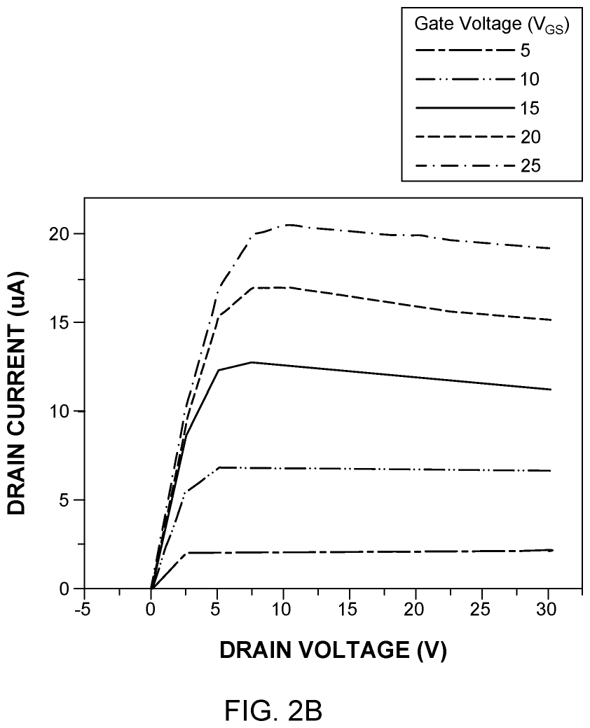

FIG. 2A shows the transfer characteristic (e.g., drain current versus gate voltage) of the transistor 100 and FIG. 2B shows the output behavior (i.e., the drain current versus the drain voltage) of the transistor. The transfer characteristics shown in FIG. 2A confirm a behavior with a decent OFF current, the linear and saturation regimes having a high current ˜35 μA at +30 V gate bias (V_{g}). It can also be observed that the transistor 100 shows a saturation current regime in the positive gate bias region attributed to the predominant electron transport in the Ga₂O₃ channel region. However, the threshold voltage is highly negative allowing the device to behave as a normal ON-transistor, which is not suitable for high power applications. The output characteristics shown in FIG. 2B indicate an appreciable linear and saturation region confirming the ideal transistor behavior having ˜20 μA at V_{ds}=30 V and V_{gs}=25 V. The threshold voltage (Vₜₕ), current ratio (Iₒₙ/I_{off}), transconductance (Gₘ), mobility and subthreshold swing (SS) for this device are measured to be around −15 V, 0.2×10⁶, 0.5×10⁻⁶ S, 0.85 cm²/V.s and 920 mV/decade, respectively. The major setbacks of the transistor 100 include having a high negative threshold, high gate leakage, and low current ratio. Another setback is that it utilizes one type of charged carriers (electrons) and thus does not have ambipolarity.

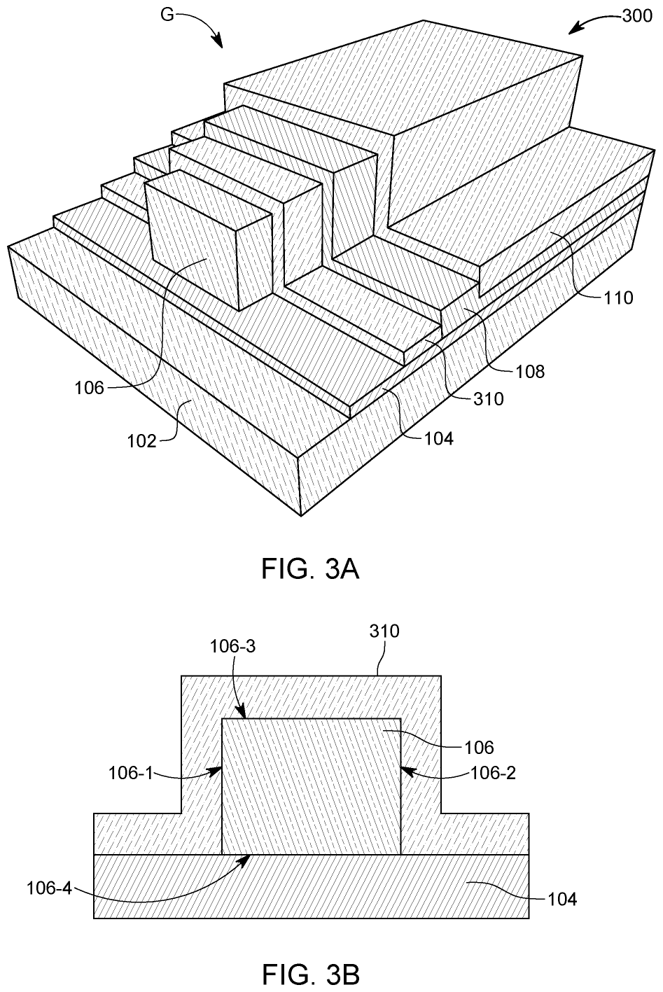

FIG. 3A shows an ambipolar transistor 300 (in fact, this figure shows only the channel region G, the source S and D regions are omitted for simplicity, but the channel region G includes the gate channel 106 and a corresponding electrode), which is a modified version of the transistor 100, in which an ultra-thin film 310 of NiO, for example, less than 10 nm (7.5 nm in one embodiment), is formed over the n-Ga₂O₃ layer 106 (the gate channel), under the dielectric layer 108 and fully covers three sides of the gate channel 106, i.e., two lateral sides 106-1 and 106-2 and one top side 106-3, as shown in FIG. 3B. Only the bottom side 106-4 of the gate channel 106 is not covered by the NiO layer 310, as also shown in FIG. 3B. FIG. 3B omits the Si substrate 102 and the electrode 110 for simplicity. Because the NiO layer 310 is a p-type semiconductor, it creates a second pn junction with the n-Ga₂O₃ layer 106, and thus the ambipolar characteristic of the transistor 300. Other materials than NiO may be used, for example, Si and GaN, as long as they are p-type semiconductors. The NiO layer helps to deplete the charges in the electron transport layer for getting good gate control and positive shift in threshold voltage.

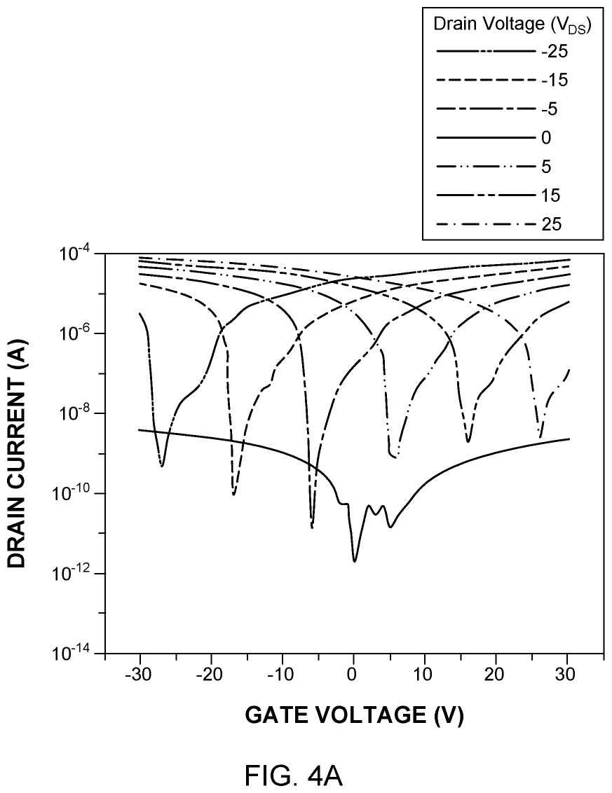

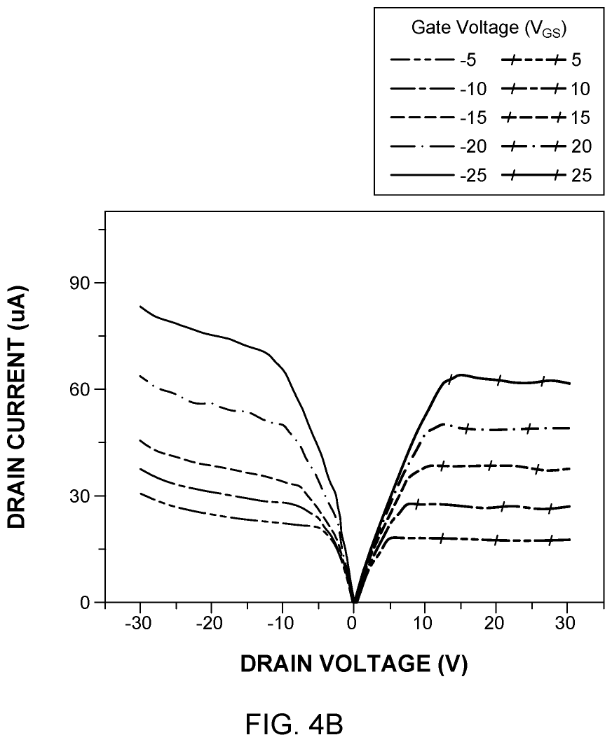

FIG. 4A shows the transfer characteristic of the ambipolar GAA transistor 300 and FIG. 4B shows the output behavior of the transistor. From FIG. 4A it can be observed a unique ambipolar behavior having an undesirable drift in the threshold voltage accompanied by a good saturation current along both positive and negative V_{g} bias conditions. Unlike the transistor 100, the average saturation current is around ˜10⁻⁴ A, i.e., about 4 orders of magnitude higher than the gate leakage current. Subsequently, from the output behavior illustrated in FIG. 4B, along the negative V_{g} and V_{d} regions, it can be seen good linear and saturation curves mainly attributed to the dominant hole transport in the NiO active channel layer. At the same time, the transistor 300 also allows good electron transport, which is confirmed by observing the current under positive V_{g} and V_{d} conditions. Nevertheless, the threshold voltage, as observed in FIG. 4B is facing a high drift that allows the transistor to stay ON always. As a consequence, the transistor 300 tends to consume more power with inefficient switching characteristics.

Hall measurements were performed for both the n-Ga₂O₃/Si and NiO/Si configurations to investigate their electronic properties. Interestingly, the bulk concentration of the gates of the transistors 100 and 300 were measured to be around 1.564×10¹⁷ and 5.211×10¹⁹/cm3, respectively. In addition to the bulk concentration of the gate of transistor 100, some of the other parameters, such as mobility, resistivity, and conductivity, confirm the use of n-Ga₂O₃ as a channel layer to achieve appreciable transistor performance. On the other hand, the intrinsic highly conductive p-type NiO layer, as confirmed from Hall measurements, shows a high probability to form good p-n junction when integrated with the n-Ga₂O₃ gate channel.

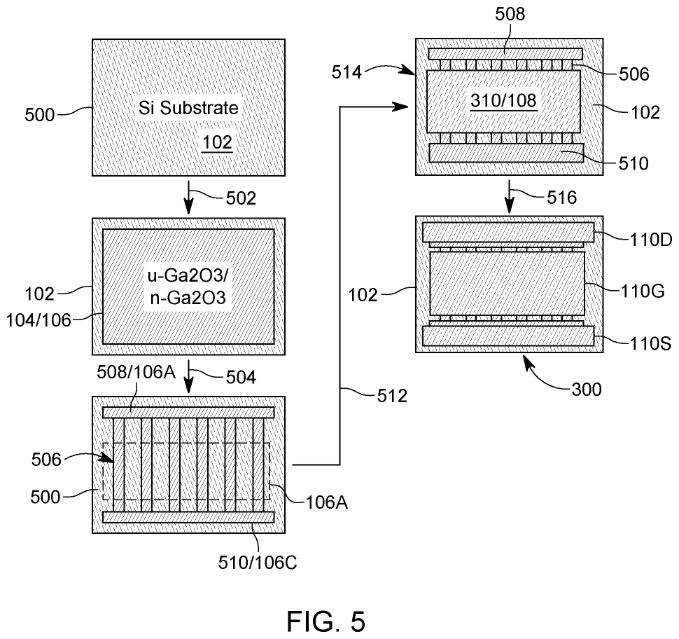

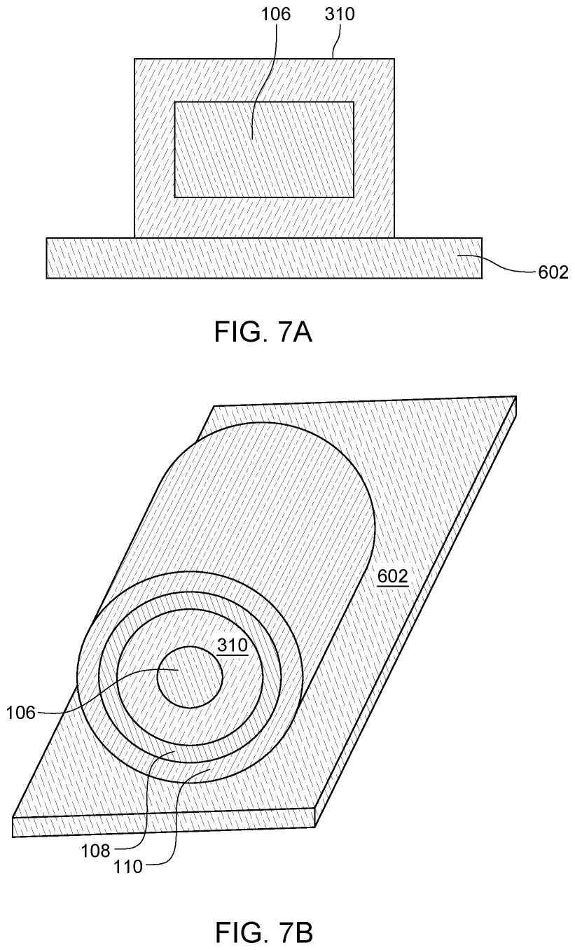

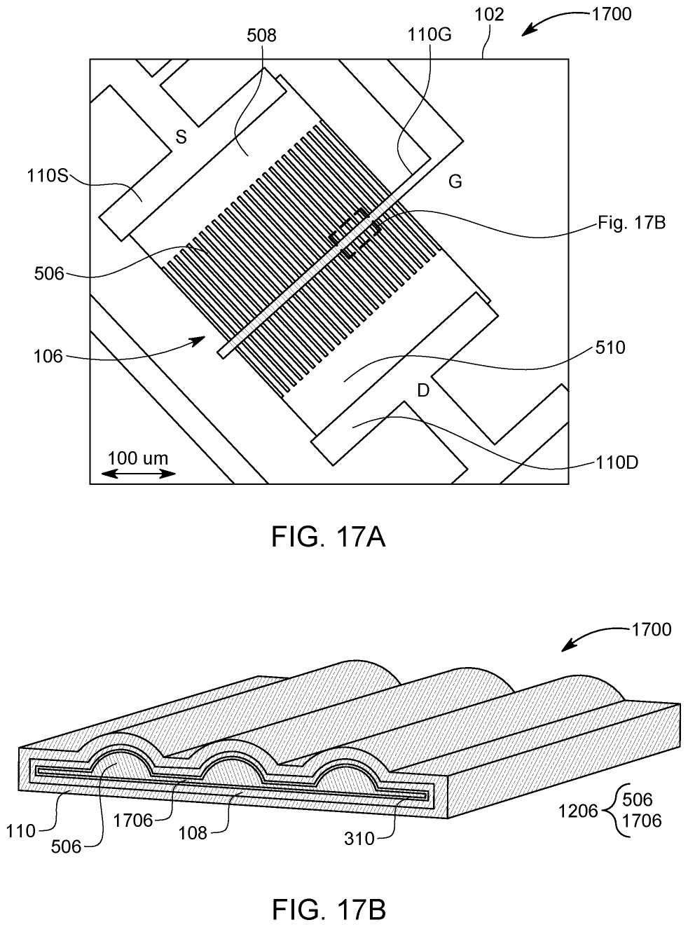

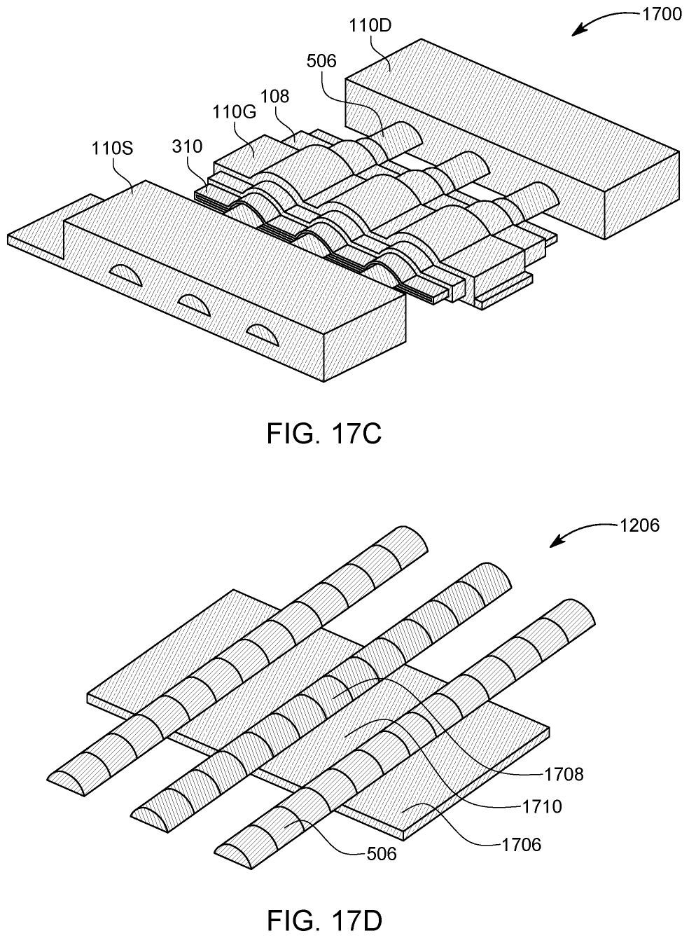

A method for manufacturing the transistor 300 is illustrated in FIG. 5. In step 500, a Si substrate 102 is provided and then cleaned. In step 502, n-Ga₂O₃/u-Ga₂O₃ are grown on the substrate 102, by using any known method, for example, physical vapor deposition or chemical vapor deposition. In step 504, the layers 104/106 of n-Ga₂O₃/u-Ga₂O₃ are etched to make fins 506, that extend from a source region 508/106B to a drain region 510/106C. Depending on the selected process, the fins 506 may be made to have a square, rectangular or cylindrical cross-section. Further, although the fins 506 are shown in the figures to extend parallel to the substrate, it is possible to make the fins to extend perpendicular to the substrate. As discussed later, the fins 506 have a central region 106A, also called the gate region, which is used as the gate channel of the transistor. In one application, each fin is a nanorod. In the following, a nanorod is considered to not include the electrode material, but only the n-type material, p-type material, and gate dielectric material. For the cylinder shape shown in FIG. 7B, the radius of the nanorod can be from 3 nanometer to 5000 nanometer. The height of the nanorod can be from 3 nanometer to 1 millimeter. The height can be smaller or larger than the radius. For the cuboid shape shown in FIG. 7A, the width and length of the nanorod can be from 3 nanometer to 5000 nanometer. The height of the nanorod can be from 3 nanometer to 1 millimeter. The height can be smaller or larger than the width or length. If other regular or irregular shapes are used, as for the dome shape discussed with regard to FIGS. 17B to 17D, the same dimensions may be used for the average shortest size of such structures.

In step 512, the NiO layer 310 is directly deposited, for example, by using ALD, over the fins 506, but not over the source region 508 or the drain region 510. Note that the NiO layer 310 fully covers the top and two lateral sides of the fins 506. Next, in step 514, the dielectric layer 108 is formed over the NiO layer 310 followed in step 516 by the formation of a gate contact 110G over the dielectric layer 108 (e.g., by RF-sputtering), and the source and drain contacts 110S and 110D over the source and drain regions 508 and 510, respectively. Note that in one embodiment, parts of the fins 506 are free, i.e., they are not covered by the layers noted above.

A cross-sectional image of the transistor 300 (not shown) was found to have the u-Ga₂O₃ layer 104 with a thickness of about 356 nm and the n-Ga₂O₃ layer 106 with a thickness of about 204 nm. The layers formed on top of the layer 106, i.e., the NiO layer 310 was found to have a thickness of about 7.5 nm and the HfO₂ layer 108 has a thickness of about 33.5 nm. Note that the n-Ga₂O₃ layer 106 has a sharp decrease, i.e., the layer 106 forms a dome (having a curved or flat top surface) while the u-Ga₂O₃ layer 104 is almost constant in cross-section.

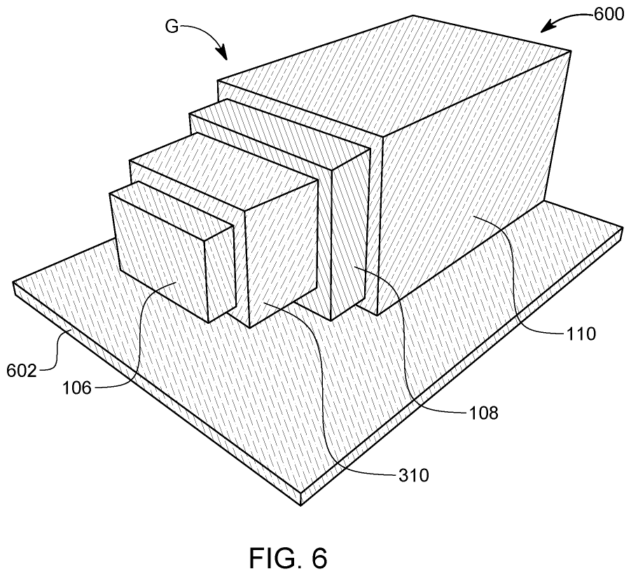

To further improve the properties of the transistor 300, according to an embodiment illustrated in FIG. 6, the NiO layer 310 is made to cover all sides of the n-Ga₂O₃ channel layer 106, which results in a monochannel GAA Ga₂O₃/NiO ambipolar gate-all-around transistor 600 (similar to FIGS. 3A and 3B, these figures show only the gate region G and not the source and drain regions). Note that the n-Ga₂O₃ channel layer 106 may be shaped to have a rectangular or square cross-section as shown in FIG. 7A, or a circular cross-section as shown in FIG. 7B. These cross-sections may also be used for the transistors discussed in other embodiments of this disclosure. Also note that the channel layer 106 may be made of other semiconductor materials, like silicon, SiGe, 2D materials, InGaAlN, SiC, III-V materials, oxides, etc. In one application, the channel layer 106 is made of a WBG material. While the figures show the channel layer 106 to extend parallel to the substrate, it is also possible to make the transistor to have the channel layer 106 made of microwires or nanowires that are perpendicular to the substrate.

The predominant reason behind the major threshold drift, as observed in the transistor 300, is mainly due to poor gate control over both electrons and holes in the channel. From literature, it is known that the best design is achieved with a recessed tri-gate structure for wide band gap semiconductor-based transistors. However, that structure still suffers from high leakage and poor gate control problems. To overcome these problems, the GAA mono-channel Ga₂O₃/NiO ambipolar transistor 600 was designed. SEM images (not shown) of the transistor 600 confirm the uniform coverage of both NiO and HfO₂ over all the sides of the 201 nm thick Ga₂O₃ material. In this embodiment, a thickness of the NiO layer 310 is about 8 nm and a thickness of the HfO₂ layer 108 is around 40 nm.

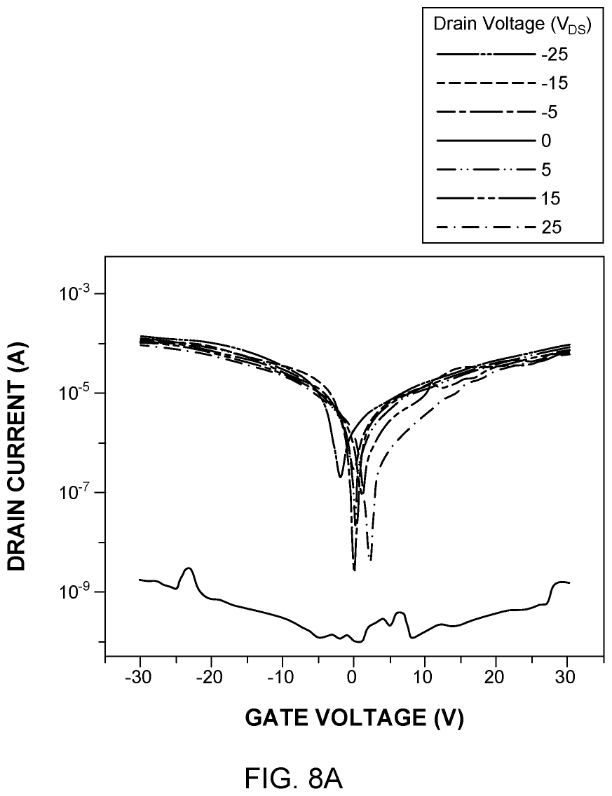

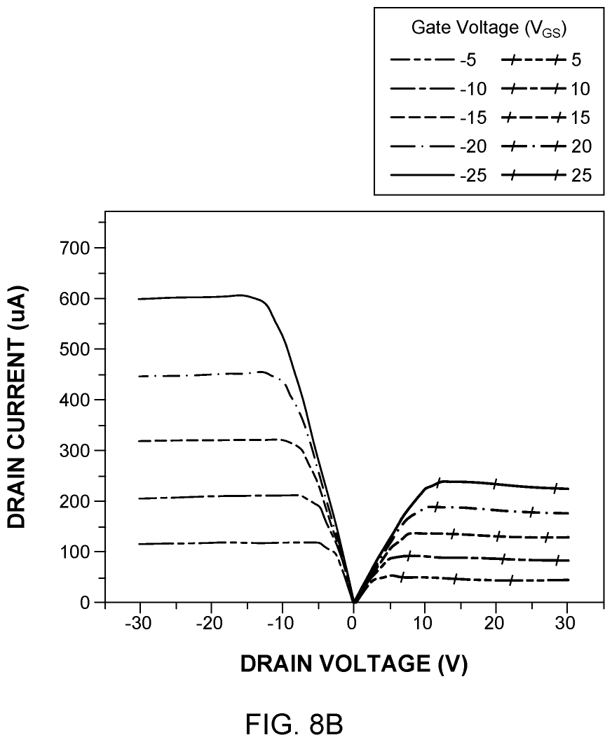

FIG. 8A shows that the gate leakage (I_{g}) and the threshold voltage drift were greatly suppressed due to the excellent gate control after successful wrapping of gate electrode on all four sides of the fins. In addition to this, it can be observed the good linear and saturation regimes along both the p-type and n-type conduction paths, as can be seen in FIG. 8B. The threshold voltage Vₜₕ, current ratio Iₒₙ/I_{off}, transconductance Gₘ, mobility and subthreshold swing SS for this structure were measured to be around 5.9 V (n-type) and −7.5 V (p-type), 7×10⁶ (n-type) and 5.5×10⁶ S (p-type), 8×10⁻⁶ (n-type) and 9.5×10⁻⁶ S (p-type), 1.1 cm²/V·s (n-type) and 0.05 cm²/V·s (p-type) and 610 mV/decade (n-type) and 552 mV/decade (p-type), respectively. However, the current density remains almost the same as for the transistor 300. It is important to note that, despite solving the aforementioned problems, under different drain bias conditions, the transistor 600 still remains to be turned ON at V_{GS}=0 V, which confirms the undesirable normally ON transistor behavior. This is one of the common problems for the transistor with ambipolar behavior because it is difficult to turn-OFF the transistor that has the high chance to transport both holes and electrons. Moreover, there is no ambipolar transistor reported with ideal OFF characteristics and low leakage response.

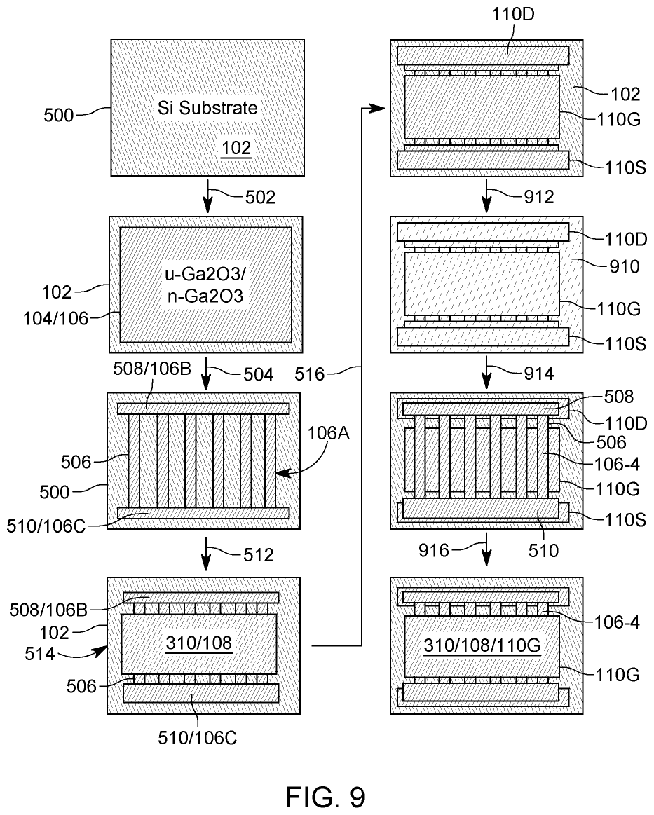

A method for making the transistor 600 is illustrated in FIG. 9. The method shares some of the steps of the method illustrated in FIG. 5 and the description of those steps is omitted herein. After the formation of the drain electrode 110D, gate electrode 110G and the source electrode 110S, the device is flipped and a Polydimethylsiloxane (PDMS) substrate 910 (which corresponds to the substrate 602 in FIG. 6, and which may be a non-silicon substrate) is formed in step 912 over the drain electrode 110D, gate electrode 110G and the source electrode 110S. In step 914, the original substrate 102 of Si is etched to complete remove it, for example, using Deep RIE process having SF6 etchant gas. This process exposes the bottom side 106-4 of the fins 506. In step 916, the bottom side 106-4 of the fins 506 are covered with the NiO layer 310, followed by the gate dielectric layer 108 and finally the gate electrode 110G so that all four sides of the fins 506 are fully enclosed by these layers.

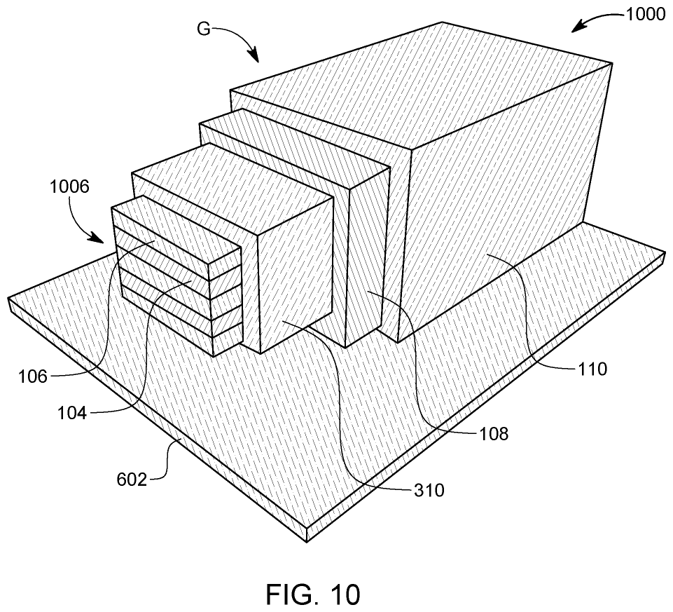

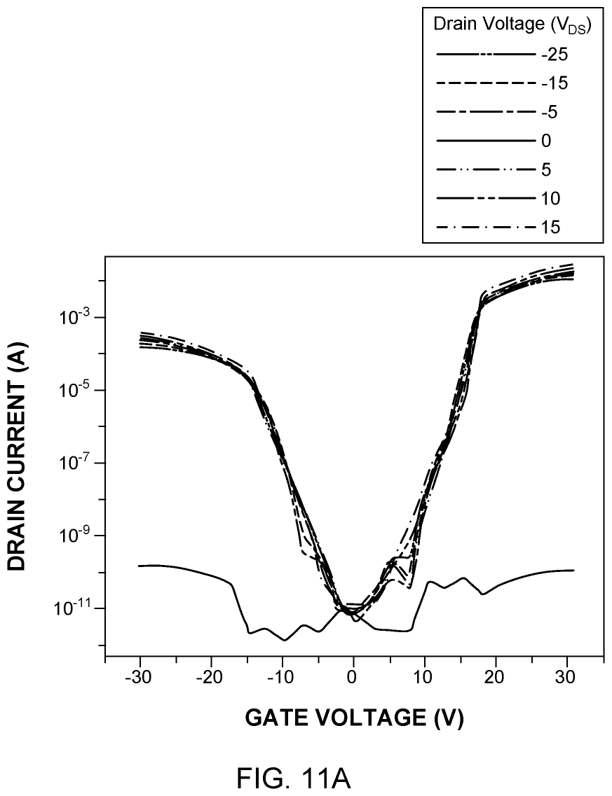

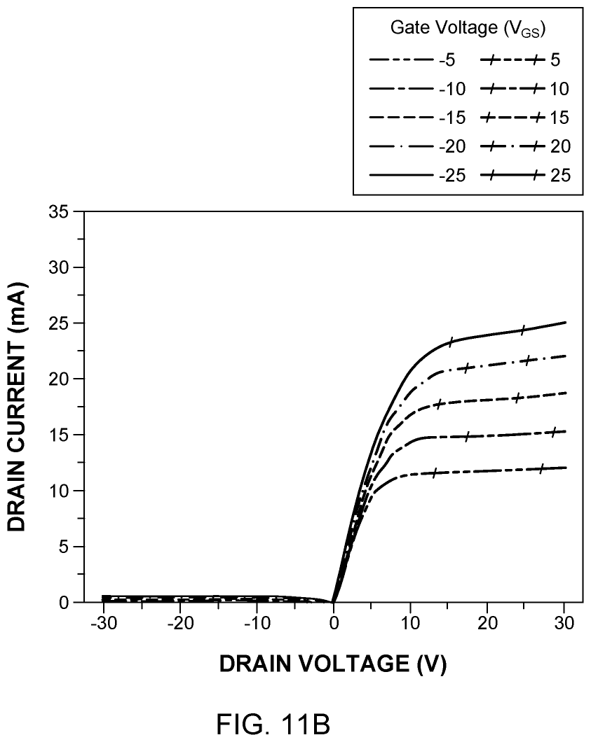

To further improve the transistor 600 shown in FIG. 6, it is possible to change the monochannel structure of the gate channel 106 to a multichannel as now discussed. FIG. 10 shows a multichannel GAA Ga₂O₃/NiO ambipolar transistor 1000 (similar to FIGS. 3 and 6, this figure shows only the gate region G and not the source and drain regions) that has the channel region formed of plural alternating layers of u-and n-Ga₂O₃ materials. This transistor was fabricated using the process of FIG. 9, but step 502 was repeated a couple of times to form the plurality of layers 104/106 for a single gate channel. Note that reference number 106 is used interchangeably to refer to a single layer of n-Ga₂O₃ or to plural layers of u- and n-Ga₂O₃. A SEM image (not shown) of the as-fabricated multichannel GAA transistor 1000 shows the ˜900 nm thick fins 506 containing multiple layers of n-Ga₂O₃ and u-Ga₂O₃ (forming a sandwich structure, i.e., they are interdigitated). The multi-layer fins 1006 are encapsulated on all four sides with the thin layers of HfO₂ and NiO, which are around 40 nm and 8 nm respectively. Unlike the transistor 600, for the first time, the transistor 1000 demonstrated the ideal turn-OFF behavior at V_{GS}=0 V, as can be seen in FIG. 11A. The threshold voltage of this transistor is around 2.5 V (n-type) and −4.2 V (p-type), which is very close to 0 V. This indicates that the transistor 1000 requires less voltage to turn-on that in-turn results in low power consumption.

From the measurements, the transistor 1000 has the lowest threshold voltage (Vₜₕ) among all the as-fabricated devices. It was found that the current ratio of this transistor is around 6×10⁹, i.e., around 3 orders of magnitude higher than the transistors 300 and 600. The transconductance Gm for the transistor 1000 was found to be around 1×10⁻³ S (n-type) and 4×10⁻⁴ S (p-type), which is two and three orders of magnitude more than the same quantity for the transistors 300 and 600, respectively. The transistor 1000 has shown charge carrier mobility around 3.23 cm²/V·s (n-type) and 0.0198 cm²/V·s (p-type). Finally, the subthreshold swing SS is around 530 mV/dec (n-type) and 510 mV/dec (p-type), which is roughly 3 times smaller than for the transistor 100. The output behavior illustrated in FIG. 11A shows a high electron transport current around 25 mA at V_{DS}=30 V and V_{GS}=25 V. However, the maximum hole transport current, because of the NiO layer, is around 0.6 mA at V_{DS}=−30 V and V_{GS}=−25 V. The major difference between the hole and electron transport current is the presence of Ga₂O₃ multichannels (fins 1006) in the channel region, unlike the NiO layer which is a monochannel wrapped around the Ga₂O₃. These multichannels help the channel gate to carry a high current that can be effectively controlled by using the gate wrapped on all the four sides. Hence, this multichannel Ga₂O₃ transistor 1000 is unique because it exhibits low threshold voltage, low subthreshold swing, excellent transconductance and exceptional charge carrier mobility.

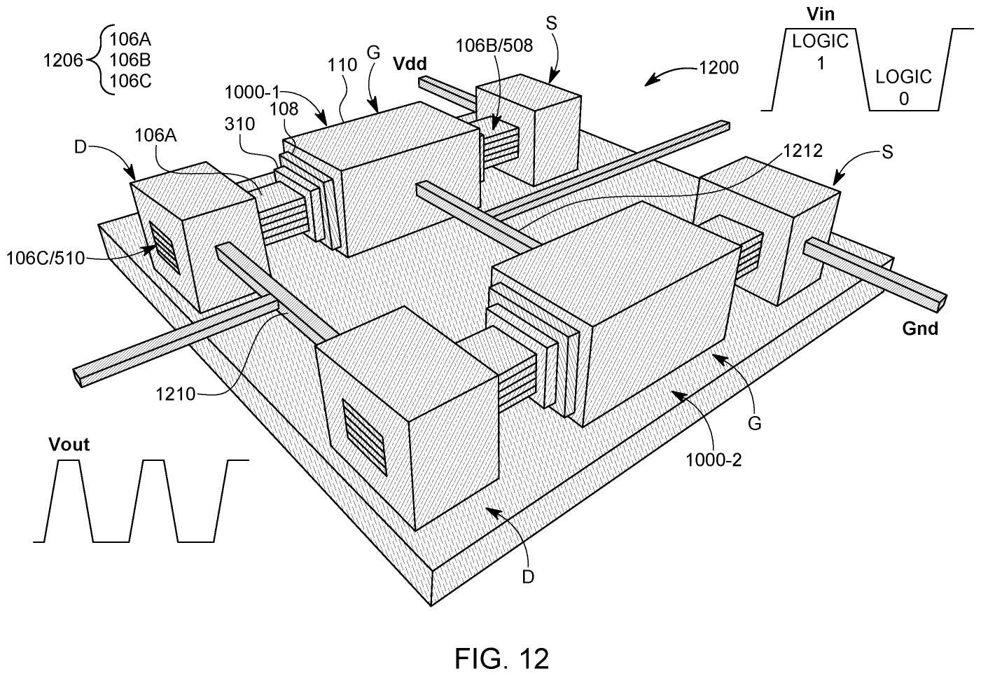

Based on the GAA ambipolar transistor 1000, the inventors have implemented a TMOS GAA ambipolar integrated circuit. More specifically, FIG. 12 shows the TMOS GAA inverter 1200 (i.e., a circuit that outputs a voltage representing the opposite logic-level to its input) that uses two identical transistors 1000-1 and 1000-2, each similar to transistor 1000. FIG. 12 labels the drain regions with D, source regions with S, and the gate regions with G. The figure also shows a wire connection 1210 between the drains of the two transistors, a wire connection 1212 between the gates of the two transistors, the application of the supply voltage V_{DD} to the source S of the first transistor 1000-1, the application of the ground voltage V_{gnd} to the source S of the second transistor 1000-2, and the application of the input voltage V_{IN} to the gate regions G of both transistors. Note that the inverter in this embodiment is configured to have the transistor 1000-1 as the p-type transistor and the transistor 1000-2 as the n-type transistor, or the other way around, depending on the applied bias. Also note that any of the transistors 300, 600 or 1000 may be used in the inverter. While FIGS. 3, 6 and 10 partially show the corresponding transistors, i.e., no drain and source regions are shown, FIG. 12 shows a full transistor 1000, including not only the channel part, but also the drain and source parts. FIG. 12 further shows that the transistor 1000 (same is true for the transistor 600) has a n-type channel structure 1206 having a gate region 106A, a source region 106B, and a drain region 106C. The amount of doping in the gate region 106A and source/drain regions may vary, i.e., they may have different doping concentrations. The same is true for the transistors 300 and 600, i.e., FIGS. 3 and 6 do not show the drain and source regions, but they are similar to those shown in FIG. 12.

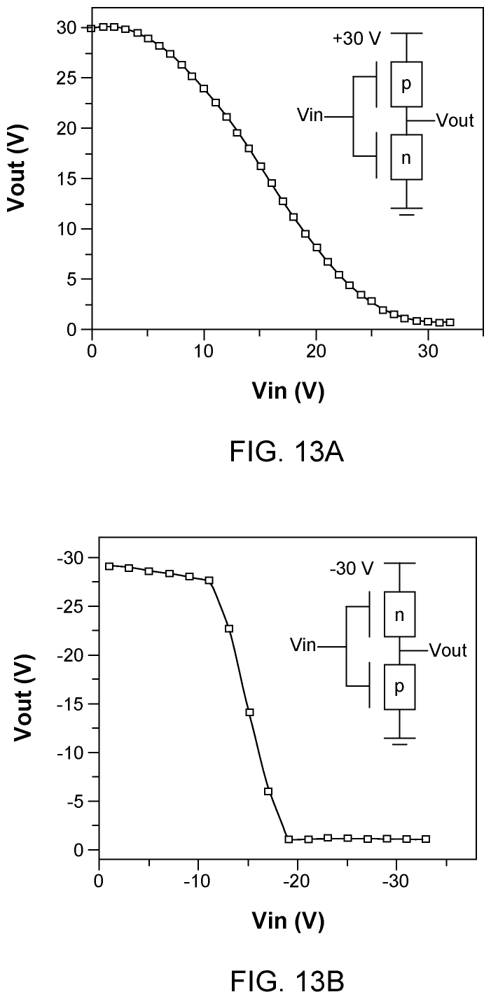

The operation mechanism of this inverter circuit is demonstrated in FIG. 13A, by first applying +30 V supply voltage (V_{DD}). It can be seen that an excellent complimentary response is obtained for the input voltage (V_{IN}) from 0 and 30 V. This is so because there is significant positive shift in the transfer response of the transistor 1000-1, which enables it to stay ON at V_{GS}=0 V with no shift observed in the transistor 1000-2. From this behavior, it can be inferred that the two transistors are acting as p-type and n-type transistors respectively. Likewise, by applying VD_{D} (−30 V), it is observed the transfer response of the first transistor being downshifted, allowing it to show dominant n-type response, and p-type behavior is observed for the second transistor (see FIGS. 13A and 13B). As a result, FIG. 13B shows that the TMOS inverter circuit is active (bit 1) when V_{IN}=0 V and turns OFF (bit 0) at V_{IN}=−30 V.

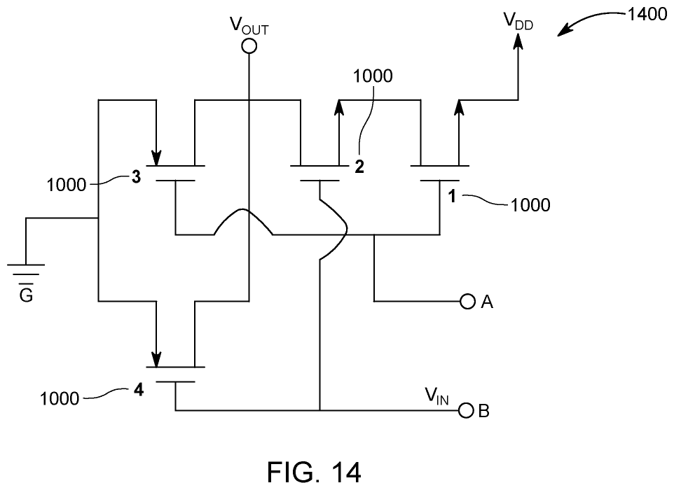

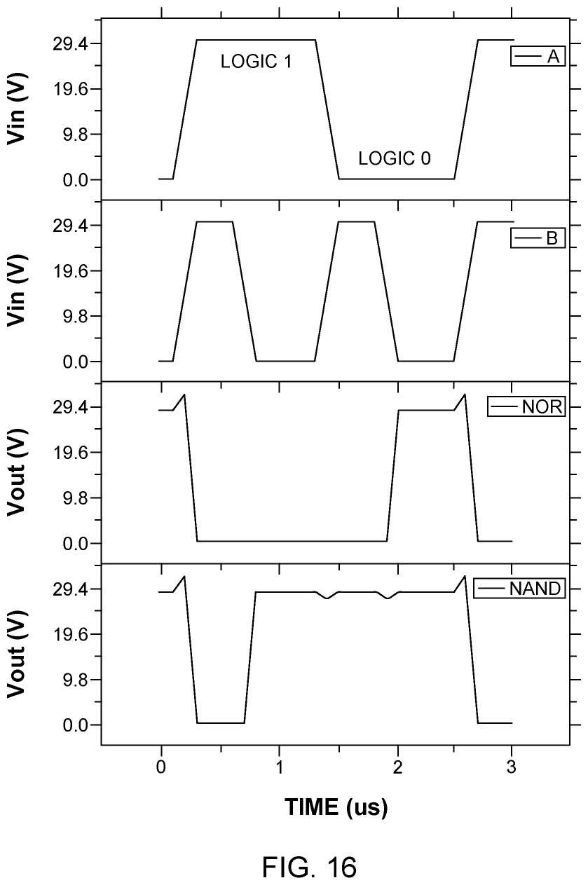

Thus, these characteristics prove a unique Ga₂O₃ based TMOS inverter circuit wherein the ambipolar transistors are able to adapt to either p-type or n-type based on the supply voltage applied. In this regard, note both the channel layer 106 or channel structure 1206 and the NiO layer 310 can be biased to change their n- and p-type character, i.e., with the right bias the channel layer 106 or channel structure 1206 can be either p- or n-type. The same is true for the NiO layer 310. Thus, it should be understood that a reference to the channel layer or channel structure being a first-type and the NiO layer being a second-type, means that the first-type can be p- or n-type while the second-type is the other one, i.e., the n- or p-type, respectively. Based on the same transistors, the inventors have built NOR and NAND circuits using four transistors 1000. It was observed, based on the circuit 1400 shown in FIG. 14, that the sources of transistors 1000-3 and 1000-4 are connected to the common ground G, and the transistor 1000-1's source is connected to the V_{DD}=30 V supply voltage. This condition allows both the first and second transistors to act as p-type behavior leaving the third and fourth transistors to exhibit electron-transport responses. Consequently, as shown in FIG. 16, the NOR logic function is achieved.

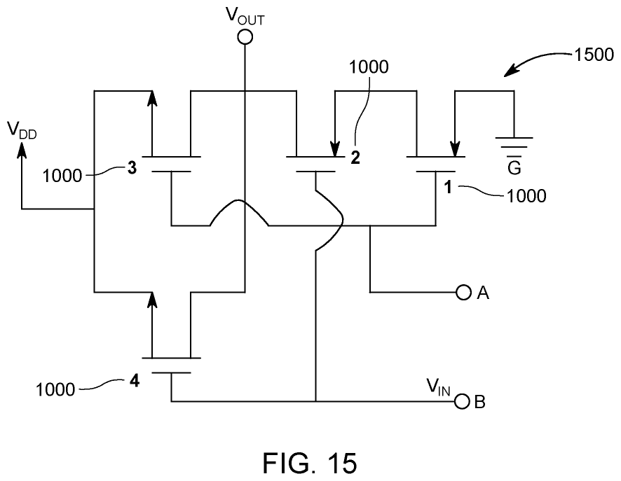

Next, the V_{DD} and ground connection were flipped for the circuit 1500 shown in FIG. 15, which resulted in the V_{DD} connection to the third and fourth transistors, and ground connection to the first transistor. Based on this condition, after applying V_{IN} (A) to the first and second transistors, and V_{IN} (B) to the third and fourth transistors, they act as n-type and p-type respectively. Based on this circuit, it is observed the NAND output response in FIG. 16 for the circuit 1500. As a result, with the help of the TMOS circuit, it was successfully demonstrated the basic inverter properties.

While the embodiments discussed above relied on having distinct (i.e., fully separated) fins 506 between the source region 508 and the drain region 510 (see FIG. 5), it is also possible to have an ambipolar Ga₂O₃ transistor with fins that are not fully separated. More specifically, FIGS. 17A and 17B show a transistor 1700 having all the layers from the transistor 600 except that part of the fins 506 are attached to each other by a thin layer 1706 of Ga₂O₃, as more clearly shown in FIG. 17B. In other words, as shown in FIG. 17C, the fins 506 of the Ga₂O₃ layer 106 are clearly separated from each other toward the source and drain contacts 110S and 110D, but they are sitting on the flat, thin layer 1706 of Ga₂O₃ in central region between the source and the drain. This means that the channel structure 1206 for this case is formed of the thin layer 1706 and the fins 506 formed on top of the thin layer 1706, both of which are made of the Ga₂O₃ material. FIG. 17D shows only the channel structure 1206 for simplicity, with the fins 506 being connected by the flat layer 1706 in the central portion of the fins 506. The Ga₂O₃ channel structure 1206 may be described as an alternate arrangement of dome-shaped fins 1708 and planar fins 1710, where the dome-shaped fins 1708 (which include a portion of each of the fin 506 and the layer 1706) has a shape different from the planar fins 1710. At a minimum, a thickness of the dome-shaped fins 1708 is larger than a thickness of the flat fins 1710. In one application, a shape of the dome-shaped fins is different from a shape of the flat fins.

FIGS. 17B and 17C also show the fin 506's length being about 375 μm. The n-Ga₂O₃ layer 106 is wrapped by a 10 nm p-NiO layer 310 to form heterojunctions, where they serve as n- and p-channels, respectively. A gate 110G with 3 μm length and defined by metal electrode 110 wraps around the heterojunctions, and includes a 35 nm HfO₂ layer 108 as gate dielectric covered by the metal electrode 110. It was found in this embodiment that the n-Ga₂O₃/p-NiO and p-NiO/HfO₂ interfaces are sharp. Other gate dielectric materials with various k values could be used separately or together as well, including Al₂O₃ and SiO₂.

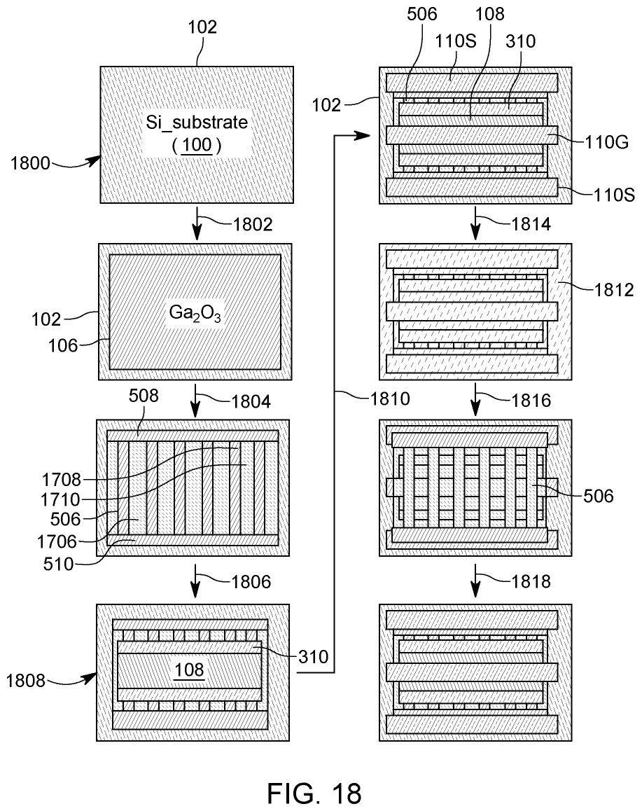

A method for making the transistor 1700 on (100) silicon substrate is now discussed with regard to FIG. 18. Although many of the steps discussed now are similar to those illustrated in FIG. 5, the full method is presented herein because of the specific gate structure 1206 that includes alternating dome-shaped fins and planar fins. The method starts in step 1800 by providing a 470 μm thick (100) silicon substrate 102, which is cleaned with an RCA process to remove residues and native oxide. Then, in step 1802, a 520 nm Ga₂O₃ layer 106 is deposited on the silicon substrate 102 using a pulsed laser deposition (PLD) system at 900° C. and oxygen partial pressure of 4 mTorr. A KrF excimer laser operated at 5 Hz with energy per pulse of 100 mJ is used for this step. Fin patterns 506 are made in step 1804 via photolithography process using a Cr mask by inductively coupled plasma-reactive ion etching (ICP-RIE) process in an Oxford Instruments system. Note that the thin layer 1706 of Ga₂O₃ is left for the middle part of the fins, i.e., not the entire layer 106 is removed during this step. The shape of some of the fins 1708 is dome shaped, due to the over etching of the original layer of Ga₂O₃. During this etching process, the Cr that was used as a hard mask was getting removed. Subsequently, some part of the Ga₂O₃ layer on the top surface was also getting etched leaving the bottom surface 1706 unaffected. As a result, the dome-shaped fins 1708 are formed. However, the etching selectivity toward Ga₂O₃:Cr has a ration of around 10:1. Afterwards, a standard Cr etchant solution may be used to remove the Cr mask, without affecting the Ga₂O₃ layer 1706 beneath. On the patterned Ga₂O₃ fins 1708 and 1710, a 10 nm NiO layer 310 is deposited in step 1806 by an atomic layer deposition (ALD) system at 250° C. and 200 mTorr. The precursors were for this step Bis (methylcyclopentadienyl) nickel and oxygen plasma for Ni and O, respectively. The NiO layer 310 was patterned by photolithography and ICP-RIE etching using a developed photoresist as a soft mask to not extend all the way to the source and drain regions 508 and 510. The mask was removed using acetone after the patterning process. Then, in step 1808, a 35 nm HfO₂ layer 108 was deposited on the NiO layer 310 by ALD. Similar to the NiO layer 310, the HfO₂ layer was patterned using ICP-RIE and the photoresist soft mask to not extend all the way to the source and drain regions 508 and 508.

Next, a magnetron sputtering system was used in step 1810 to deposit a 10-nm Ti/95-nm Au stack as metal electrodes 110 for the gate, source and drain regions on the front side. Then, the wafer was flipped leaving the backside of the silicon substrate 102 as the top surface and manually bonded the flipped wafer on a 400 μm thick PDMS cured substrate 1812 in step 1814. This PDMS-bonded flipped wafer was then subjected in step 1816 to deep RIE to completely remove the entire silicon substrate 102, to expose the back sides of the fins 506 and layer 1706. Then, in step 1818, the 10-nm NiO layer 310 and the 35-nm HfO₂ layer 108 were deposited by ALD and patterned to cover the backside, followed by sputtering of the 10-nm Ti/95-nm Au stack 110 to complete the fabrication process to form the gate-all-around p-around-n-channel transistors shown in FIGS. 17A to 17D. The transistor 1700 may be used in the circuits 1400 and 1600 instead of the transistor 1000 if desired. In fact, any of the Ga₂O₃ transistors discussed herein may be used in the circuits of FIGS. 14 and 16.

The disclosed embodiments provide plural ambipolar Ga₂O₃ transistors. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. An ambipolar, gate all around, semiconductor-based transistor comprising:
a substrate;
a first-type channel structure located on the substrate, the first-type channel structure having a gate region, a source region, and a drain region;
a second-type material located on an entire external surface of the gate region of the first-type channel structure, but not on the source region and the drain region;
a dielectric material fully surrounding the second-type material on an entire external surface of the gate region (106A);
a gate electrode located on the dielectric material;
a source electrode located on the source region; and
a drain electrode located on the drain region,
wherein the first-type material is one of p- or n-type and the second-type material is another of the p- or n-type.

2. The transistor of claim 1, wherein the channel structure is made of a Ga₂O₃ material that includes a single layer of undoped Ga₂O₃ and a single layer of n-doped Ga₂O₃.

3. The transistor of claim 1, wherein the channel structure is made of a Ga₂O₃ material that includes plural layers of undoped Ga₂O₃ interdigitated with plural layers of n-doped Ga₂O₃.

4. The transistor of claim 1, wherein the gate region comprises:
plural fins extending from the source region to the drain region.

5. The transistor of claim 4, wherein each fin of the plural fins is a nanorod.

6. The transistor of claim 5, wherein each nanorod has a central region comprising the first-type material fully enclosed by the second-type material.

7. The transistor of claim 4, wherein gate region further comprises:
a flat layer of Ga₂O₃,
wherein the plural fins are distributed on top of the flat layer of Ga₂O₃ so that dome-shaped fins and flat fins are formed, and
wherein each of the dome-shaped fins includes (1) a corresponding fin of the plural fins and (2) a portion of the flat layer of Ga₂O₃, and each flat fin includes another portion of the flat layer of Ga₂O₃.

8. The transistor of claim 7, wherein the dome-shaped fins and the flat fins are interdigitated.

9. The transistor of claim 7, wherein a thickness of the dome-shaped fins is larger than a thickness of the flat fins.

10. The transistor of claim 1, wherein the second-type material is NiO.

11. An inverter comprising:
a first ambipolar, gate all around, semiconductor-based transistor having (1) a first-type channel structure made of a semiconductor material and (2) a second-type material;
a second ambipolar, gate all around, semiconductor-based transistor having (1) another first-type channel structure made of the semiconductor material and (2) another second-type material;
a first electrical connection between drain regions (D) of the first and second ambipolar, gate all around, semiconductor-based transistors; and
a second electrical connection between source regions(S) of the first and second ambipolar, gate all around, semiconductor-based transistors,
wherein the first-type is one of p- or n-type and the second type is another of the p- or n-type.

12. The invertor of claim 11, wherein the second-type material fully encloses a region of the first-type channel structure, and the another second-type material fully encloses a region of the another first-type channel structure.

13. The invertor of claim 12, wherein the second-type material and the another second-type material include NiO.

14. The invertor of claim 11, wherein each of the first and second ambipolar, gate all around, semiconductor-based transistors comprises:
a substrate;
the first-type channel structure located on the substrate, the first-type channel structure having a gate region, a source region, and a drain region;
the second-type material located on an entire external surface of the gate region of the first-type channel structure, but not on the source region and the drain region;
a dielectric material fully surrounding the second-type material on an entire external surface of the gate region (106A);
a gate electrode located on the dielectric material;
a source electrode located on the source region; and
a drain electrode located on the drain region,
wherein the semiconductor material is a Ga₂O₃ material.

15. The inverter of claim 14, wherein the Ga₂O₃ material includes a single layer of undoped Ga₂O₃ and a single layer of n-doped Ga₂O₃.

16. The inverter of claim 14, wherein the Ga₂O₃ material includes plural layers of undoped Ga₂O₃ interdigitated with plural layers of n-doped Ga₂O₃.

17. The inverter of claim 14, wherein the gate region comprises:
plural fins extending from the source region to the drain region.

18. The inverter of claim 17, wherein each fin of the plural fins is a nanorod and each nanorod has a central region fully enclosed by the second-type material.

19. The inverter of claim 18, wherein the gate region further comprises:
a flat layer of Ga₂O₃,
wherein the plural fins are distributed on top of the flat layer of Ga₂O₃ so that dome-shaped fins and flat fins are formed, and
wherein each of the dome-shaped fins includes a corresponding fin of the plural fins and a portion of the flat layer of Ga₂O₃, and each flat fin includes another portion of the flat layer of Ga₂O₃.

20. A method of making an ambipolar, gate all around, semiconductor-based transistor, the method comprising:
providing a first substrate;
growing a first-type channel structure on the first substrate, the first-type channel structure having a gate region, a source region, and a drain region;
etching the gate region to form plural fins;
depositing a second-type material on all but one portion of the gate region of the first-type channel structure, but not on the source region and the drain region;
forming a dielectric material to surround the second-type material on all but one portion of the gate region;
depositing a gate electrode on the dielectric material, a source electrode on the source region, and a drain electrode on the drain region;
forming a second substrate on the first-type channel structure;
removing the first substrate; and
depositing the second-type material on the one portion of the gate region so that an entire external surface of the gate region are covered by the second-type material,
wherein the channel structure is made of a Ga₂O₃ material.
